(19) United States
(12) Patent Application Publication
(10) Pub. No.: US 2010/0243057 A1
(43) Pub. Date: Sep. 30, 2010

(54) SEMICONDUCTOR DEVICE, PHOTOELECTRIC CONVERTER AND METHOD FOR MANUFACTURING PHOTOELECTRIC CONVERTER

(75) Inventors: Goro NAKATANI, Kyoto (JP); Osamu Matsushima, Kyoto (JP); Takamitsu Yamanaka, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/730,211

(22) Filed: Mar. 23, 2010

(30) Foreign Application Priority Data
Mar. 24, 2009 (JP) 2009-072561
Apr. 9, 2009 (JP) 2009-095193
Mar. 23, 2010 (JP) 2010-065681

(51) Int. Cl. H01L 31/00; H01L 31/0264; H01L 31/18; H01L 31/12

(52) U.S. Cl. 136/261; 257/431; 438/95; 257/E31.004; 257/E31.095

(57) ABSTRACT

The semiconductor device according to the present invention includes: a semiconductor substrate; an integrated circuit formed on the semiconductor substrate; and a photoelectric converter, stacked on the integrated circuit, having a light absorbing layer made of a compound semiconductor having a chalcopyrite structure.

### BACKGROUND OF THE INVENTION

1. Field of the Invention

The present invention relates to a semiconductor device mixedly provided with a photoelectric converter and an integrated circuit, a photoelectric converter employing a chalcopyrite-based compound semiconductor as the material for a light absorbing layer and a method for manufacturing the same.

2. Description of Related Art

For example, a semiconductor device mixedly provided with a solar cell and an LSI is known as a self-generable semiconductor device requiring no external power supply.

In such a semiconductor device, a solar cell chip and an LSI chip are aligned with each other on a substrate, and electrically connected with each other by a wire.

### SUMMARY OF THE INVENTION

However, the size of the aforementioned semiconductor device is inevitably increased due to the employment of the substrate having a space for receiving the two chips (the solar cell chip and the LSI chip).

On the other hand, downsizing has recently been required in the field of electronic devices such as semiconductor devices. If the size of each chip is reduced in order to downsize the semiconductor device, however, a photoreceiving area of the solar cell is reduced as a result, and hence the quantum efficiency of the solar cell is reduced. Therefore, the two chips are preferably not aligned with each other.

For example, the solar cell and the LSI may be stacked with each other.

In this case, the LSI must be first formed on a semiconductor substrate so that the solar cell is stacked on the LSI to be arranged on the outermost layer of the semiconductor device, in order to ensure a large photoreceiving surface for the solar cell.

However, the solar cell simply stacked on the LSI may exert a bad influence on the LSI. If the solar cell is formed by a silicon thin film, for example, the substrate is heated to a temperature of about 1400° C. in formation of the silicon thin film. Therefore, a wire of the LSI prepared in advance is disadvantageously melted.

Such a disadvantage takes place also in a case of stacking another photoelectric converter such as an image sensor, for example, and the LSI with each other.

An object of the present invention is to provide a semiconductor device allowing stacking of a photoelectric converter and an integrated circuit without remarkably reducing the quantum efficiency of the photoelectric converter and without exerting a bad influence on the integrated circuit.

Another object of the present invention is to provide a photoelectric converter and a method for manufacturing the same, each capable of improving and uniformizing sensitivity of a light absorbing layer and reducing the manufacturing cost.

The foregoing and other objects, features and effects of the present invention will become more apparent from the following detailed description of the embodiments with reference to the attached drawings.

### BRIEF DESCRIPTION OF THE DRAWINGS

FIG. 1 is a block diagram showing the electric structure of a semiconductor device according to a first embodiment of the present invention.

FIG. 2A is a schematic plan view of the semiconductor device according to the first embodiment of the present invention.

FIG. 2B is an enlarged view of a principal part of the semiconductor device shown in FIG. 2A.

FIGS. 3(a), 3(b) and 3(c) are schematic sectional views of the semiconductor device according to the first embodiment of the present invention taken along a line IIIa-IIIa in FIG. 2A, a line IIIb-IIIb in FIG. 2B and a line IIIc-IIIc in FIG. 2A respectively.

FIGS. 4A to 4K are schematic sectional views showing a method for manufacturing the semiconductor device shown in FIGS. 3(a) to 3(c).

FIG. 5 is a schematic sectional view of a semiconductor device according to a second embodiment of the present invention.

FIG. 6 is a schematic sectional view of a semiconductor device according to a third embodiment of the present invention.

FIG. 7 is a block diagram showing the electric structure of a semiconductor device according to a fourth embodiment of the present invention.

FIG. 8A is a schematic plan view of the semiconductor device according to the fourth embodiment of the present invention.

FIG. 8B is an enlarged view of a principal part of the semiconductor device shown in FIG. 8A.

FIGS. 9(a), 9(h) and 9(c) are schematic sectional views of the semiconductor device according to the fourth embodiment of the present invention taken along a line IXa-IXa in FIG. 8A, a line IXb-IXb in FIG. 8B and a line IXc-IXc in FIG. 8A respectively.

FIGS. 10A to 10I are schematic sectional views showing a method for manufacturing the semiconductor device shown in FIGS. 9(a) to 9(c).

FIG. 11 is a schematic plan view of a semiconductor device according to a fifth embodiment of the present invention.

FIG. 12 is a schematic plan view of a semiconductor device according to a sixth embodiment of the present invention.

### DETAILED DESCRIPTION OF PREFERRED EMBODIMENTS

A semiconductor device according to an embodiment of the present invention includes a semiconductor substrate, an integrated circuit formed on the semiconductor substrate, and a photoelectric converter, stacked on the integrated circuit, having a light absorbing layer made of a compound semiconductor having a chalcopyrite structure.

According to the structure, the integrated circuit is formed on the semiconductor substrate, and the photoelectric converter is stacked and arranged on the integrated circuit. The integrated circuit and the photoelectric converter can be arranged in such a stacked manner, since the light absorbing layer of the photoelectric converter is made of the compound semiconductor having the chalcopyrite structure. This is because the compound semiconductor having the chalcopyrite structure can be grown at a relatively low temperature of less than 400° C., for example, so that influence exerted on the integrated circuit can be reduced in formation of the photoelectric converter.

The integrated circuit and the photoelectric converter can be arranged in a stacked manner, to be integrated into one chip. Consequently, the semiconductor device can be inhibited from increase in size.

The photoelectric converter is stacked and arranged on the integrated circuit, whereby generally the overall region of the area where the photoelectric converter is arranged can be utilized as the photoreceiving surface of the photoelectric converter. Therefore, a photoelectric converter capable of sufficiently ensuring a photoreceiving area can be designed, whereby reduction in the quantum efficiency of the photoelectric converter can be suppressed.

In the semiconductor device, a solar cell may be constituted of a plurality of photoelectric converters, and the semiconductor device may further include a power supply circuit electrically connecting the solar cell and the integrated circuit with each other.

According to the structure, the solar cell and the integrated circuit are electrically connected with each other through the power supply circuit. When the solar cell receives light, therefore, power is supplied to the integrated circuit. Thus, the integrated circuit can be operated through the power from the solar cell, with no requirement for separate power supply. Further, a power supply device can be omitted, whereby the semiconductor device can be downsized.

In the semiconductor device, an image sensor may be constituted of a plurality of photoelectric converters, and the semiconductor device may further include a signal circuit electrically connecting the image sensor and the integrated circuit with each other.

According to the structure, the image sensor and the integrated circuit are electrically connected with each other through the signal circuit. When the image sensor receives light, therefore, electric signals are input in the integrated circuit. The integrated circuit can detect the light input in the image sensor as image information by processing the signals received from the plurality of photoelectric converters.

When the image sensor is used together with the solar cell, the integrated circuit can process the signals received from the image sensor with the power supplied from the solar cell.

Preferably in the semiconductor device, the light absorbing layer contains Ga.

According to the structure, the quantum efficiency of the photoelectric converter can be improved due to the light absorbing layer containing Ga.

In the semiconductor device, the photoelectric converter may include a first insulating layer, a lower electrode formed on the first insulating layer, and a second insulating layer, laminated on the first insulating layer, having a recess including the upper surface of the lower electrode in the bottom surface thereof. In this case, the light absorbing layer is embedded in the recess and the upper surface thereof is a photoreceiving surface, while an upper electrode made of a light-transmitting material is formed on the light absorbing layer. The surface area of the photoreceiving surface is not less than the opening area of the recess. In other words, the surface area of the photoreceiving surface is not less than the area (the plane area) of the recess in plan view.

According to the structure, the lower electrode is formed on the first insulating layer. The second insulating layer is laminated on the first insulating layer. The recess including the upper surface of the lower electrode in the bottom surface thereof is formed in the second insulating layer. The light absorbing layer is embedded in the recess. The light absorbing layer is made of the chalcopyrite-based compound semiconductor. The upper electrode made of the light-transmitting material is formed on the light absorbing layer.

The upper surface of the light absorbing layer serves as the photoreceiving surface, and the surface area (the photoreceiving area) of the photoreceiving surface is not less than the opening area of the recess. Therefore, the photoreceiving area can be enlarged by rendering the opening area of the recess as large as possible, for improving the sensitivity of the light absorbing layer due to the enlarged photoreceiving area.

The light absorbing layer is obtained by forming the recess in the second insulating layer and embedding the chalcopyrite-based compound semiconductor employed as the material for the light absorbing layer in the recess. A technique of precisely forming recesses in a layer made of an insulating material such as SiO₂ has already been established, and hence the recesses can be precisely formed so that the recesses are uniform in size, while rendering the interval therebetween as small as possible. Therefore, a large size can be ensured for the light absorbing layers, without dispersion. Consequently, the light absorbing layers can be improved and uniformized in sensitivity.

Further, no step is required for patterning the light absorbing layer by etching, and hence the manufacturing cost can be reduced due to omission of a photolithography step for the patterning.

In the semiconductor device, the opening area of the recess may be greater than the area of the upper surface of the lower electrode, and the bottom surface of the recess may include the overall region of the upper surface of the lower electrode. Thus, the surface area of the photoreceiving surface can be rendered greater than that of the upper surface of the lower electrode, whereby the sensitivity of the light absorbing layer can be further improved.

In the semiconductor device, the photoreceiving surface may be flush with the upper surface of the second insulating layer. In this case, the opening area and the photoreceiving area coincide with each other. The light absorbing layer having the photoreceiving surface can be formed by filling up the recess with the material for the light absorbing layer and chemically mechanically polishing the light absorbing layer until the upper surface of the second insulating layer is exposed.

Preferably, a buffer layer is interposed between the light absorbing layer and the upper electrode. The light absorbing layer and the upper electrode are made of the materials different from each other, and hence the lattice constants are also different from each other. When the upper electrode is directly laminated on the light absorbing layer, therefore, stress may be caused in the light absorbing layer and/or the upper electrode due to the difference between the lattice constants, to result in lattice defects. The stress caused by the difference between the lattice constants can be relaxed due to the buffer layer interposed between the light absorbing layer and the upper electrode, whereby the light absorbing layer and the upper electrode can be prevented from lattice defects.

Preferably, a step is formed in the photoreceiving surface between a peripheral edge portion of the photoreceiving surface and a central portion surrounded by the peripheral edge portion. The area of the photoreceiving surface exceeds the opening width of the recess due to the formation of the step. Therefore, the sensitivity of the photoelectric converter can be further improved.

The step may be formed by lowering the central portion of the photoreceiving surface by one stage below the peripheral edge portion of the photoreceiving surface.

A photoelectric converter according to another embodiment of the present invention includes a first insulating layer, a lower electrode formed on the first insulating layer, a second insulating layer, laminated on the first insulating layer, having a recess including the upper surface of the lower electrode in the bottom surface thereof, a light absorbing layer, made of a chalcopyrite-based compound semiconductor and embedded in the recess, having an upper surface serving as a photoreceiving surface, and an upper electrode made of a light-transmitting material formed on the light absorbing layer. The surface area of the photoreceiving surface is not less than the opening area of the recess. In other words, the surface area of the photoreceiving surface is not less than the area (the plane area) of the recess in plan view.

In the photoelectric converter, the lower electrode is formed on the first insulating layer. The second insulating layer is laminated on the first insulating layer. The recess including the upper surface of the lower electrode in the bottom surface thereof is formed in the second insulating layer. The light absorbing layer is embedded in the recess. The light absorbing layer is made of the chalcopyrite-based compound semiconductor. The upper electrode made of the light-transmitting material is formed on the light absorbing layer.

The upper surface of the light absorbing layer serves as the photoreceiving surface, and the surface area (the photoreceiving area) of the photoreceiving surface is not less than the opening area of the recess. Therefore, the photoreceiving area can be enlarged by rendering the opening area of the recess as large as possible, for improving the sensitivity of the light absorbing layer due to the enlarged photoreceiving area.

The light absorbing layer is obtained by forming the recess in the second insulating layer and embedding the chalcopyrite-based compound semiconductor employed as the material for the light absorbing layer in the recess. The technique of precisely forming recesses in a layer made of an insulating material such as SiO₂ has already been established, and hence the recesses can be precisely formed so that the recesses are uniform in size, while rendering the interval therebetween as small as possible. Therefore, a large size can be ensured for the light absorbing layers, without dispersion. Consequently, the light absorbing layers can be improved and uniformized in sensitivity.

Further, no step is required for patterning the light absorbing layer by etching, and hence the manufacturing cost can be reduced due to omission of a photolithography step for the patterning.

In the photoelectric converter, the opening area of the recess may be greater than the area of the upper surface of the lower electrode, and the bottom surface of the recess may include the overall region of the upper surface of the lower electrode. Thus, the surface area of the photoreceiving surface can be rendered greater than that of the upper surface of the lower electrode, whereby the sensitivity of the light absorbing layer can be further improved.

In the photoelectric converter, the photoreceiving surface may be flush with the upper surface of the second insulating layer. In this case, the opening area and the photoreceiving area coincide with each other. The light absorbing layer having the photoreceiving surface can be formed by filling up the recess with the material for the light absorbing layer and chemically mechanically polishing the light absorbing layer until the upper surface of the second insulating layer is exposed.

Preferably, a buffer layer is interposed between the light absorbing layer and the upper electrode. The light absorbing layer and the upper electrode are made of the materials different from each other, and hence the lattice constants thereof are also different from each other. When the upper electrode is directly laminated on the light absorbing layer, therefore, stress may be caused in the light absorbing layer and/or the upper electrode due to the difference between the lattice constants, to result in lattice defects. The stress caused by the difference between the lattice constants can be relaxed due to the buffer layer interposed between the light absorbing layer and the upper electrode, whereby the light absorbing layer and the upper electrode can be prevented from lattice defects.

The photoelectric converter can be formed by a method including the steps of laminating an electrode material layer made of a material for a lower electrode on a first insulating layer, laminating a sacrificial layer on the electrode material layer, selectively removing the sacrificial layer and the electrode material layer by photolithography and etching, forming a second insulating layer on the first insulating layer so that at least the removed portions of the sacrificial layer and the electrode material layer are filled up to the upper surface of the sacrificial layer, chemically mechanically polishing the second insulating layer for exposing the upper surface of the sacrificial layer to be flush with the upper surface of the second insulating layer, removing the sacrificial layer by isotropic etching after the chemical mechanical polishing of the second insulating layer, depositing a chalcopyrite-based compound semiconductor to fill up a recess formed in the second insulating layer due to the removal of the sacrificial layer, and chemically mechanically polishing the deposition layer of the chalcopyrite-based compound semiconductor for forming a light absorbing layer embedded in the recess.

According to the method, the photolithography step for forming the photoelectric converter can be carried out only once. As compared with a conventional method for manufacturing a photoelectric converter, therefore, the manufacturing steps can be simplified and the manufacturing cost can be reduced.

Embodiments of the present invention are now described in detail with reference to the attached drawings.

### First to Third Embodiments

### 1. Electric Structure of Semiconductor Device

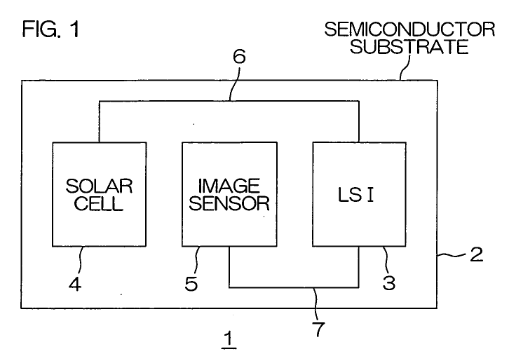

FIG. 1 is a block diagram showing the electric structure of a semiconductor device according to a first embodiment of the present invention.

In a semiconductor device 1, an LSI 3, a solar cell 4 and an image sensor 5 are mixedly provided on a semiconductor substrate 2.

The LSI 3 and the solar cell 4 are electrically connected with each other by a power supply line 6 as a power supply circuit. Thus, the LSI 3 and the solar cell 4 are electrically conductible through the power supply line 6. When the solar cell 4 receives light, therefore, power is supplied to the LSI 3.

The LSI 3 and the image sensor 5 are electrically connected with each other by a signal line 7 as a signal circuit insulated from the power supply line 6. Thus, the LSI 3 and the image sensor 5 are electrically conductible through the signal line 7. When the image sensor 5 receives light, therefore, electrons resulting therefrom are converted by a charge reading device (not shown) such as a CMOS device or a CCD to an electric signal, which in turn is input in the LSI 3.

### 2. Plane Structure of Semiconductor Device

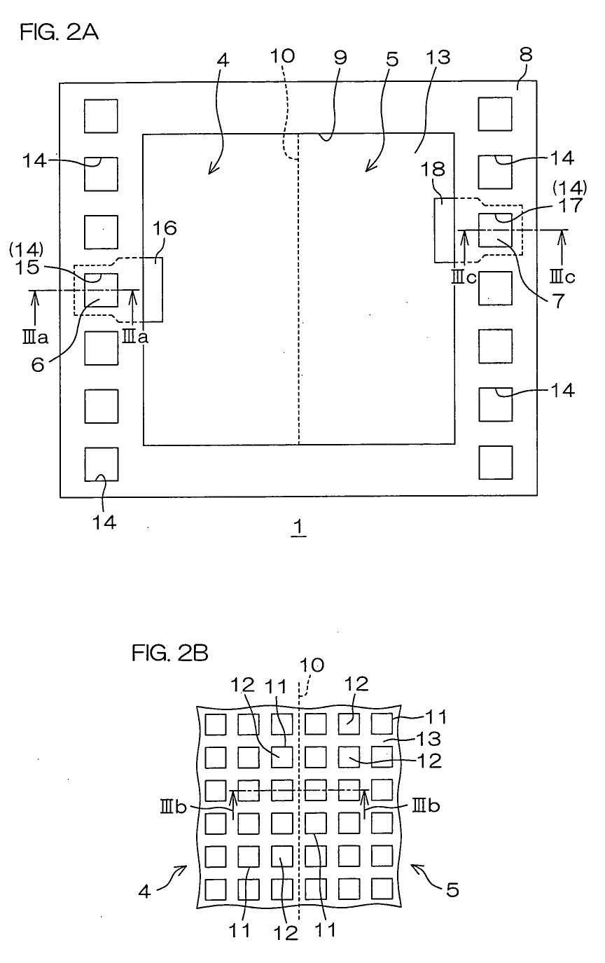

FIG. 2A is a schematic plan view of the semiconductor device 1 according to the first embodiment of the present invention. FIG. 2B is an enlarged view of a principal part of the semiconductor device 1 shown in FIG. 2A.

The semiconductor device 1 is quadrangular in plan view. The surface of the semiconductor device 1 is covered with a surface protective film 8 made of silicon nitride.

A photoreceiving opening 9 exposing a central portion of the semiconductor device 1 is formed in the surface protective film 8. The photoreceiving opening 9 is quadrangularly formed in plan view similarly to the semiconductor device 1, so that the sides thereof are parallel to those of the semiconductor device 1. The solar cell 4 and the image sensor 5 face the exterior of the semiconductor device 1 through the photoreceiving opening 9.

When the photoreceiving opening 9 is divided into two rectangular regions line-symmetrical in plan view along a dividing line 10, the solar cell 4 and the image sensor 5 are arranged in one region (a right region in FIGS. 2A and 2B) and another region (a left region in FIGS. 2A and 2B) of the photoreceiving opening 9 respectively, and adjacent to each other through the dividing line 10.

Each of the solar cell 4 and the image sensor 5 has a plurality of photoelectric converters 11 identical in structure to one another, and is constituted of a set of the plurality of photoelectric converters 11. The plurality of photoelectric converters 11 are arranged in the form of a matrix over the entire region of the photoreceiving opening 9. Each photoelectric converter 11 of the solar cell 4 is the minimum generating unit (unit cell) converting light energy to power, while each photoelectric converter 11 of the image sensor 5 is one pixel of image information.

The dividing line 10 demarcating the solar cell 4 and the image sensor 5 from each other is set between the photoelectric converters 11 of the solar cell 4 and those of the image sensor 5.

The plurality of photoelectric converters 11 arranged in the aforementioned manner have photoreceiving surfaces 12 on portions facing the exterior of the semiconductor device 1 respectively. All photoreceiving surfaces 12 are integrally covered with an upper electrode 13. In other words, an electrode (the upper electrode 13) on photoreceiving sides of the solar cell 4 and the image sensor 5 is shared by all photoelectric converters 11 without distinction of the solar cell 4 or the image sensor 5.

In the surface protective film 8, a plurality of pad openings 14 are formed on both sides of the photoreceiving opening 9 in the adjacent direction (orthogonal to the dividing line 10) of the solar cell 4 and the image sensor 5, to be separated from the photoreceiving opening 9. The plurality of pad openings 14 are provided on both sides of the photoreceiving opening 9 in the same numbers respectively, and arranged at regular intervals in a direction parallel to the dividing line 10.

A wire electrically connected with the LSI 3 is exposed in each pad opening 14. One of the plurality of pad openings 14 arranged on one side of the photoreceiving opening 9 is a power supply pad opening 15 exposing the power supply line 6. The power supply line 6 exposed from the power supply pad opening 15 is electrically connected with the upper electrode 13 by a power extraction electrode 16 (made of Al, for example) extending over the photoreceiving opening 9 and the power supply pad opening 15.

On the other hand, one of the plurality of pad openings 14 arranged one the other side of the photoreceiving opening 9 is a signal pad opening 17 exposing the signal line 7. The signal line 7 exposed from the signal pad opening 17 is electrically connected with the upper electrode 13 by a signal extraction electrode 18 (made of Al, for example) extending over the photoreceiving opening 9 and the signal pad opening 17.

### 3. Sectional Structure of Semiconductor Device

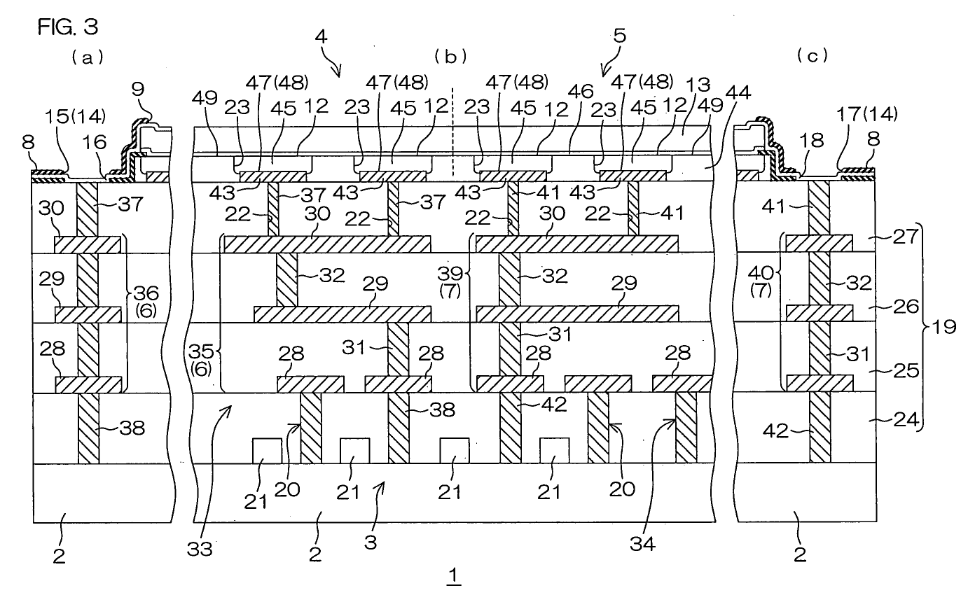

FIGS. 3(a), 3(b) and 3(c) are schematic sectional views of the semiconductor device 1 according to the first embodiment of the present invention taken along a line IIIa-IIIa in FIG. 2A, a line IIIb-IIIb in FIG. 2B and a line IIIc-IIIc in FIG. 2A respectively.

In the semiconductor device 1, the LSI 3, the solar cell 4 and the image sensor 5 are stacked and arranged on the semiconductor substrate 2. More specifically, the LSI 3 is formed on the semiconductor substrate 2, and an interlayer film 19 is laminated on the LSI 3. The solar cell 4 and the image sensor 5 are arranged on the interlayer film 19 to be adjacent to each other. Thus, the solar cell 4 and the image sensor 5 are stacked on the LSI 3 through the interlayer film 19.

The semiconductor substrate 2 is made of silicon, for example. The semiconductor substrate 2 is 2 mm to 7 mm square, and has a thickness of 200 μm to 725 μm, for example.

The LSI 3 includes a plurality of types of circuit elements 21. The plurality of types of circuit elements 21 include transistors (Tr), capacitors (C), registers (R) and the like, for example.

The interlayer film 19 is made of silicon oxide, and formed by laminating a first interlayer film 24, a second interlayer film 25, a third interlayer film 26 and a fourth interlayer film 27 as a first insulating layer successively from the side closer to the LSI 3.

First to third wires 28 to 30 are formed on the interlayer films 24 to 26 successively from the side of the first interlayer film 24 respectively. The first to third wires 28 to 30 are made of Al (melting point: about 500° C.), for example.

First via plugs 31 passing through the second interlayer film 25 and second via plugs 32 passing through the third interlayer film 26 electrically connect the first and second wires 28 and 29 and the second and third wires 29 and 30 with one another respectively. The first and second via plugs 31 and 32 are made of W (melting point: about 3400° C.), for example. The first to third wires 28 to 30 are electrically connected with one another over the first to third interlayer films 24 to 26, thereby forming a multilayer interconnection structure 33 extending over the first to third interlayer films 24 to 26.

The multilayer interconnection structure 33 at least includes the power supply line 6 electrically connecting the solar cell 4 and the LSI 3 with each other and the signal line 7 electrically connecting the image sensor 5 and the LSI 3 with each other, and additionally includes interelement circuits 20 electrically connecting the plurality of types of circuit elements 21 with one another and partially forming the LSI 3 and an output circuit 34 transmitting signals output from the LSI 3, for example.

The power supply line 6 has an anode power supply wire 35 and a cathode power supply wire 36. The anode power supply wire 35 is arranged under the solar cell 4. Power supply via plugs 37 electrically connect the anode power supply wire 35 and the solar cell 4 with each other, while a power supply contact plug 38 electrically connects the anode power supply wire 35 and the LSI 3 with each other. The power supply via plugs 37 and the power supply contact plug 38 are made of W (melting point: about 3400° C.), for example.

On the other hand, the cathode power supply wire 36 is arranged on a side portion of the solar cell 4. The power extraction electrode 16 and a power supply via plug 37 electrically connect the cathode power supply wire 36 and the solar cell 4 with each other, while a power supply contact plug 38 electrically connects the cathode power supply wire 36 and the LSI 3 with each other.

The signal line 7 has an anode signal wire 39 and a cathode signal wire 40. The anode signal wire 39 is arranged under the image sensor 5. Signal via plugs 41 electrically connect the anode signal wire 39 and the image sensor 5 with each other, while a signal contact plug 42 electrically connects the anode signal wire 39 and the LSI 3 with each other. The signal via plugs 41 and the signal contact plug 42 are made of W (melting point: about 3400° C.), for example.

On the other hand, the cathode signal wire 40 is arranged on a side portion of the image sensor 5. The signal extraction electrode 18 and a signal via plug 41 electrically connect the cathode signal wire 40 and the image sensor 5 with each other, while a signal contact plug 42 electrically connects the cathode signal wire 40 and the LSI 3 with each other.

The photoelectric converters 11 constituting the solar cell 4 and the image sensor 5 include lower electrodes 43, an insulating layer 44 as a second insulating layer, light absorbing layers 45, a high-resistance buffer layer 46 and the upper electrode 13.

The lower electrodes 43 are made of Mo (molybdenum) or W (tungsten), for example, and plurally arrayed and formed on the fourth interlayer film 27 in the form of a matrix. According to the first embodiment, each lower electrode 43 corresponds to the unit cell of the solar cell 4 or one pixel of the image sensor 5. In the fourth interlayer film 27, via holes 22 passing through the fourth interlayer film 27 in the laminating direction thereof are formed on positions where the third wires 30 and the lower electrodes 43 are opposed to one another respectively, and the power supply via plugs 37 and the signal via plugs 41 are embedded in the via holes 22. Thus, each lower electrode 30 is electrically connected with the corresponding third wire 43 through the corresponding power supply via plug 37 or the corresponding signal via plug 41.

The insulating layer 44 is laminated on the fourth interlayer film 27 and the lower electrodes 43. The insulating layer 44 is made of SiO₂, for example. In the insulating layer 44, recesses 23 dug down from the upper surface thereof are formed correspondingly to the lower electrodes 43 respectively. The recesses 23 are formed to project sideward beyond the lower electrodes 43 in sectional view so that the opening area thereof is greater than the area of upper surfaces 47 of the lower electrodes 43, and include the overall regions of the upper surfaces 47 of the lower electrodes 43 in bottom surfaces 48 thereof. The depth of the recesses 23 is 1 μm, for example.

The light absorbing layers 45 are formed in the recesses 23. The light absorbing layers 45 are made of a P-type chalcopyrite-based compound semiconductor.

The compound semiconductor of the chalcopyrite structure has the same crystal structure as chalcopyrite, and is expressed in a composition formula I-III-VI₂ or II-IV-V₂, for example. The Roman numerals in the composition formulas correspond to group numbers of the periodic table. For example, the Roman numerals I and II represent a group IB element and a group IIB element respectively.

In each composition formula, the group IB element corresponds Cu or Ag, for example, the group IIIB element corresponds to Al, Ga or In, for example, and the group VIB element corresponds to S, Se or Te, for example.

The group IIB element corresponds to Zn or Cd, for example, the group IVB element corresponds to Si, Ge or Sn, for example, and the group VB element corresponds to P, As or Sb, for example.

As the compound semiconductor having the chalcopyrite structure, a I-III-VI₂ type chalcopyrite compound semiconductor is preferably applied, and a CIGS-based semiconductor expressed as Cu(Inₓ,Ga₍₁₋ₓ₎)Se₂ (0≦x≦1) is more preferably applied. In particular, the chalcopyrite compound semiconductor preferably contains Ga (i.e., 0≦x≦1).

Semiconductors different from the CIGS-based semiconductor include I-III-VI₂ type semiconductors such as CuAlS₂, CuAlSe₂, CuAlTe₂, CuGaS₂, CuGaSe₂, CuGaTe₂, CuInS₂, CuInTe₂, AgAlS₂, AgAlSe₂, AgAlTe₂, AgGaS₂, AgGaSe₂, AgGaTe₂, AgInS₂, AgInSe₂ and AgInTe₂, and II-IV-V₂ type semiconductors such as ZnSiP₂, ZnSiAs₂, ZnSiSb₂, ZnGeP₂, ZnGeAs₂, ZnGeSb₂, ZnSnP₂, ZnSnAs₂, ZnSnSb₂, CdSiP₂, CdSiAs₂, CdSiSb₂, CdGeP₂, CdGeAs₂, CdGeSb₂, CdSnP₂, CdSnAs₂ and CdSnSb₂, for example, and any of such semiconductors is also applicable.

The upper surfaces of the light absorbing layers 45 are the photoreceiving surfaces 12, which are generally flush with an upper surface 49 of the insulating layer 44. Therefore, the surface area (a photoreceiving area) of the photoreceiving surfaces 12 coincides with the opening area of the recesses 23. The recesses 23 are formed to project sideward beyond the lower electrodes 43 in sectional view, whereby the insulating layer 44 is present under peripheral edge portions of the light absorption layers 45.

The high-resistance buffer layer 46 is formed on the insulating layer 44 and the light absorbing layers 45. The high-resistance buffer layer 46 is made of CdS (cadmium sulfide). The high-resistance buffer layer 46 covers the overall regions of the upper surface 49 of the insulating layer 44 and the upper surfaces (the photoreceiving surfaces 12) of the light absorbing layers 45. The thickness of the high-resistance buffer layer 46 is 500 Å (50 nm), for example.

The upper electrode 13 is laminated on the high-resistance buffer layer 46. The upper electrode 13 is made of ZnO (zinc oxide) having light transmissibility. An N-type impurity (P (phosphorus) or As (arsenic), for example) is added to ZnO, to provide conductivity. In other words, the upper electrode 13 is a transparent electrode having conductivity. The thickness of the upper electrode 13 is 6000 Å (600 nm), for example. The upper electrode 13 is electrically connected with the cathode power supply wire 36 through the power extraction electrode 16 and the corresponding power supply via plug 37 (see FIG. 3(a)), and electrically connected with the cathode signal wire 40 through the signal extraction electrode 18 and the corresponding signal via plug 41 (see FIG. 3(c)).

### 4. Method for Manufacturing Semiconductor Device

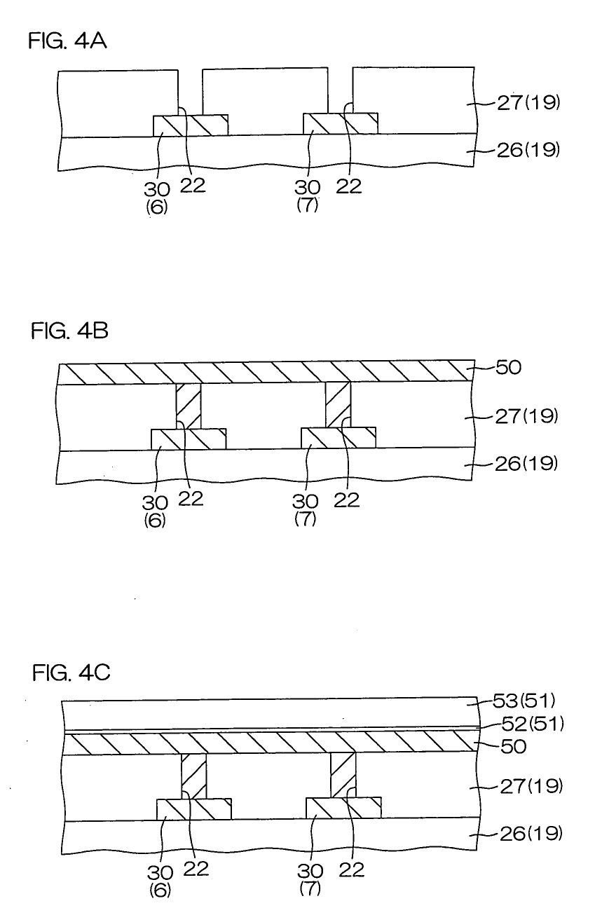

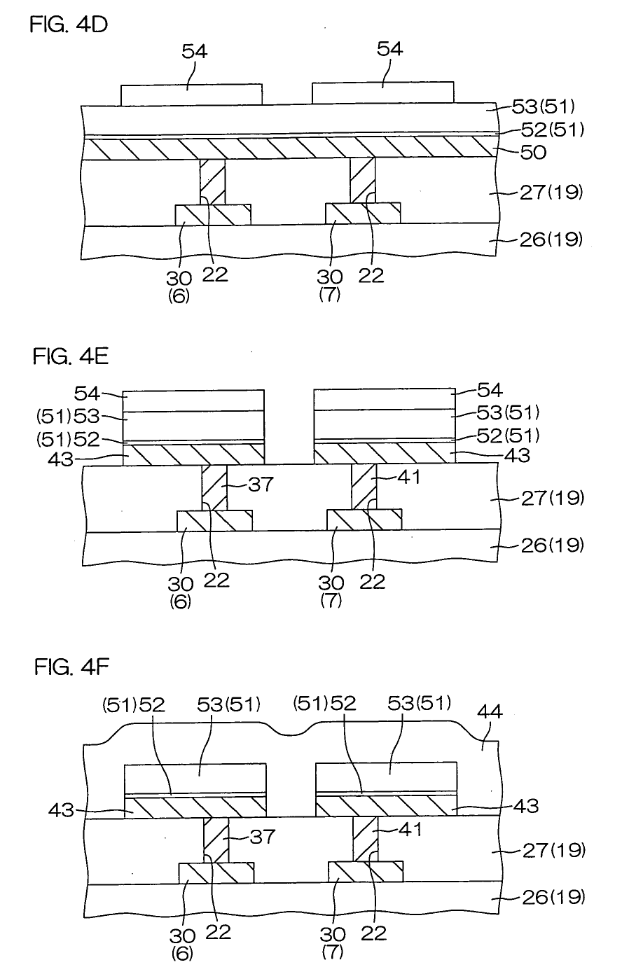

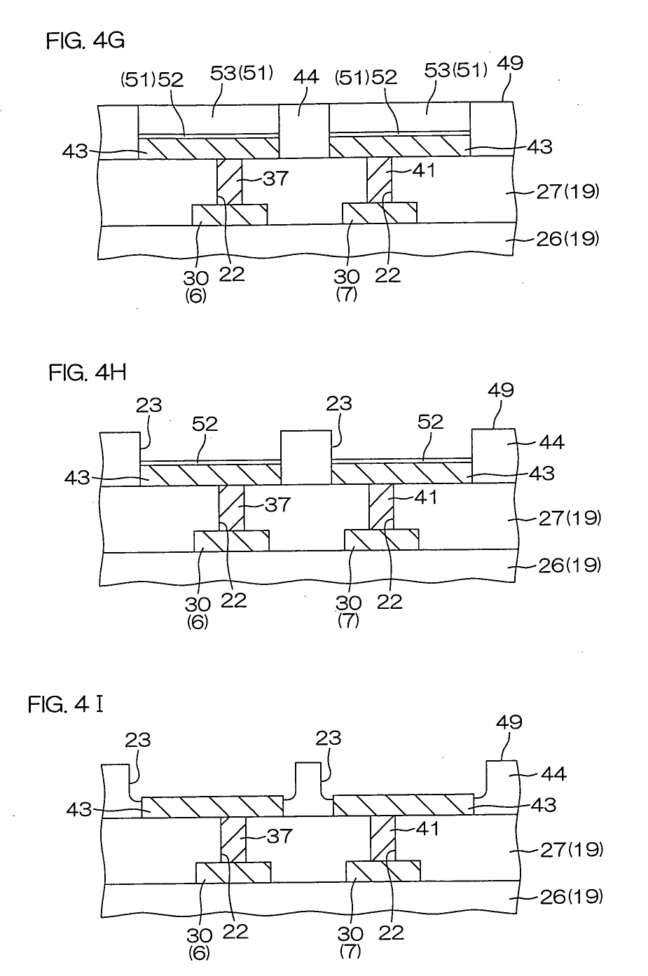

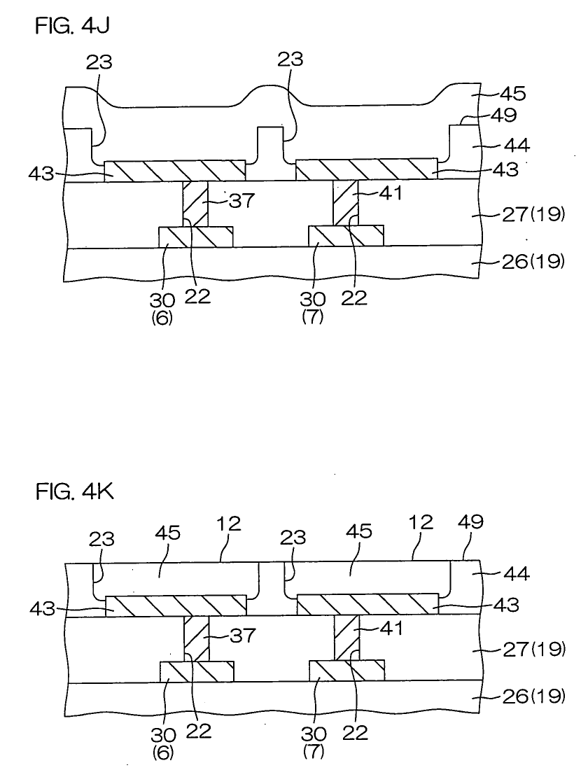

FIGS. 4A to 4K are schematic sectional views showing a method for manufacturing the semiconductor device 1 shown in FIGS. 3(a) to 3(c). Each of FIGS. 4A to 4K shows one of the photoelectric converters 11 constituting the solar cell 4 and one of those constituting the image sensor 5.

In order to manufacture the aforementioned semiconductor device 1, the various types of circuit elements 21 are first loaded on the semiconductor substrate 2 by a well-known element integration technique. Then, the interlayer film 19 as well as the power supply line 6 and the signal line 7 are formed by a well-known multilayer interconnection technique. Then, the fourth interlayer film 27 is selectively etched, thereby forming the via holes 22 partially exposing the upper surfaces of the third wires 30 to pass through the fourth interlayer film 27, as shown in FIG. 4A.

Then, an electrode material layer 50 made of W is formed on the fourth interlayer film 27 including the inner portions of the via holes 22 by CVD, as shown in FIG. 4B. The electrode material layer 50 is formed in a thickness for filling up the via holes 22.

Then, a sacrificial layer 51 is laminated on the electrode material layer 50 by PECVD (Plasma Enhanced Chemical Vapor Deposition), as shown in FIG. 4C. More specifically, an etching stopper layer 52 made of TEOS (Tetraethoxysilane) is first formed on the electrode material layer 50. Then, an SiN layer 53 made of SiN (silicon nitride) is formed on the etching stopper layer 52. The etching stopper layer 52 is formed in a thickness of 300 Å (30 nm), for example. The SiN layer 53 is formed in a thickness for finally obtaining the light absorbing layers 45 of a desired thickness, in consideration of the quantities of polishing of the light absorbing layers 45 described later. When the thickness of the light absorbing layers 45 is 1 μm, the thickness of the SiN layer 53 is set to 12000 Å (1.2 μm), for example.

Thereafter resist films 54 covering portions for forming the lower electrodes 43 (see FIGS. 3(a) to 3(c)) are formed on the SiN layer 53 by photolithography, as shown in FIG. 4D.

Thereafter the sacrificial layer 51 and the electrode material layer 50 are etched through the resist films 54 serving as masks, whereby the electrode material layer 50 is patterned into the lower electrodes 43 of respective pixel units while the power supply via plug 37 and the signal via plug 41 embedded in the via holes 22 are obtained, as shown in FIG. 4E. After the formation of the lower electrodes 43, the resist films 54 are removed.

Then, the insulating layer 44 is laminated on the fourth interlayer film 27 and the sacrificial layer 51 by CVD, as shown in FIG. 4F. The insulating layer 44 is so formed that the upper surface thereof is higher than that of the sacrificial layer 51 in the portions where the sacrificial layer 51 and the lower electrodes 43 have been partially removed.

Thereafter the insulating layer 44 is polished by CMP, as shown in FIG. 4G. The insulating layer 44 is continuously polished until the upper surface 49 of the insulating layer 44 and the upper surface of the sacrificial layer 51 are flush with each other.

Then, the SiN layer 53 is removed by dry etching, for example, as shown in FIG. 4H. Thus, the recesses 23 are formed in the insulating layer 44 to be dug down from the upper surface 49 thereof.

Then, the etching stopper layer 52 is removed by wet etching with hydrofluoric acid, as shown in FIG. 4I. At this time, the insulating layer 44 is also etched, whereby the opening width of the recesses 23 is so spread that the recesses 23 project sideward beyond the lower electrodes 43 in sectional view.

Thereafter the light absorbing layers 45 are formed on the insulating layer 44 including the inner portions of the recesses 23 by MBE, as shown in FIG. 4J. The light absorbing layers 45 are formed in a thickness for filling up the recesses 23.

Then, the light absorbing layers 45 are polished by CMP, as shown in FIG. 4K. The light absorbing layers 45 are polished until the upper surfaces (the photoreceiving surfaces 12) thereof and the upper surface 49 of the insulating layer 44 are flush with one another.

Then, the high-resistance buffer layer 46 and the upper electrode 13 are laminated on the insulating layer 44 and the light absorbing layers 45 in this order from the side of the interlayer film 19. Thus, the semiconductor device 1 shown in FIGS. 3(a) to 3(c) is obtained.

In the semiconductor device 1, the interlayer film 19 is laminated on the semiconductor substrate 2 provided with the LSI 3, and the solar cell 4 and the image sensor 5 are stacked and arranged on the LSI 3 through the interlayer film 19. The solar cell 4 and the image sensor 5 can be stacked and arranged on the LSI 3 since the light absorbing layers 45 of the photoelectric converters 11 are made of the compound semiconductor having the chalcopyrite structure. This is because the compound semiconductor having the chalcopyrite structure can be formed by MBE at a temperature of 300° C. to 450° C., for example, and hence influence exerted on the LSI 3 by the formation of the photoelectric converters 11 can be reduced. For example, the first to third wires 28 to 30 can be prevented from melting.

The solar cell 4 and the image sensor 5 can be stacked and arranged on the LSI 3, whereby the LSI 3, the solar cell 4 and the image sensor 5 can be integrated into one chip. Consequently, the semiconductor device 1 can be inhibited from increase in size.

Further, the solar cell 4 and the image sensor 5 are stacked and arranged on the LSI 3, whereby generally the overall regions of arrangement areas on the interlayer film 19 can be employed as the photoreceiving surfaces 12 of the photoelectric converters 11. Therefore, the degree of freedom in design of the size of the photoelectric converters 11 can be increased. Thus, the open area ratio of the photoelectric converters 11 constituting the solar cell 4 and the image sensor 5 respectively can be set to 80% to 100%, for example. Consequently, a sufficient photoreceiving area can be ensured for the photoelectric converters 11, whereby reduction in the quantum efficiency of the photoelectric converters 11 can be suppressed.

The solar cell 4 and the LSI 3 are electrically connected with each other through the power supply line 6. When light is introduced from the photoreceiving surfaces 12 of the photoelectric converters 11 of the solar cell 4, therefore, electrons in the N-type upper electrode 13 are extracted by the power extraction electrode 16 due to the light energy, and supplied to the LSI 3 through the cathode power supply wire 36. The electrons are continuously supplied while the solar cell 4 receives the light, whereby a current flows from the light absorbing layers 45 to successively reach the anode power supply wire 35, the LSI 3, the cathode power supply wire 36, the power extraction electrode 16 and the upper electrode 13. Thus, power is supplied to the LSI 3.

Therefore, the LSI 3 can be operated with no requirement for separate power supply. Further, a power supply device can be omitted, whereby the semiconductor device 1 can be downsized.

The image sensor 5 and the LSI 3 are electrically connected with each other through the signal line 7. When light is introduced from the photoreceiving surfaces 12 of the photoelectric converters 11 of the image sensor 5, therefore, electrons in the upper electrode 13 generated by the light energy are converted by the charge reading device to electric signals, which in turn are thereafter extracted by the signal extraction electrode 18 and input in the LSI 3 through the cathode signal wire 40. The electric signals are continuously input while the image sensor 5 receives the light, whereby the electric signals flow from the light absorbing layers 45 to successively reach the anode signal wire 39, the LSI 3, the cathode signal wire 40, the signal extraction electrode 18 and the upper electrode 13.

The image sensor 5 and the solar cell 4 are used together, whereby the LSI 3 can process signals received from the plurality of photoelectric converters 11 constituting the image sensor 5 with the power supplied from the solar cell 4. Thus, the LSI 3 can detect the light input in the image sensor 5 as image information.

When the light absorbing layers 45 contain Ga, the quantum efficiency of the photoelectric converters 11 can be improved. For example, excellent quantum efficiency of about 80% to 90% can be implemented.

In the semiconductor device 1, the lower electrodes 43 are formed on the fourth interlayer film 27. The insulating layer 44 is laminated on the fourth interlayer film 27. The recesses 23 including the upper surfaces 47 of the lower electrodes 43 in the bottom surfaces 48 thereof are formed in the insulating layer 44. The light absorbing layers 45 are embedded in the recesses 23. The light absorbing layers 45 are made of CIGS. The upper electrode 13 made of ZnO is formed on the light absorbing layers 45.

The upper surfaces of the light absorbing layers 45 are the photoreceiving surfaces 12, which are flush with the upper surface 49 of the insulating layer 44. Therefore, the surface area (the photoreceiving area) of the photoreceiving surfaces 12 coincides with the opening area of the recesses 23. Thus, the photoreceiving area can be enlarged by rendering the opening area of the recesses 23 as large as possible, and the sensitivity of the light absorbing layers 45 can be improved due to the enlargement of the photoreceiving area.

The light absorbing layers 45 are obtained by forming the recesses 23 in the insulating layer 44 and embedding CIGS employed as the material for the light absorbing layers 45 in the recesses 23. The technique of precisely forming recesses in a layer made of an insulating material such as SiO₂ has already been established, and hence the recesses 23 can be precisely formed so that the recesses 23 are uniform in size, while rendering the interval therebetween as small as possible. Therefore, a large size can be ensured for the light absorbing layers 45, without dispersion. Consequently, the light absorbing layers 45 can be improved and uniformized in sensitivity.

Further, a step of patterning the light absorbing layers 45 by etching can be omitted, whereby the manufacturing cost can be reduced due to omission of a photolithography step for the patterning.

The high-resistance buffer layer 46 is interposed between the light absorbing layers 45 and the upper electrode 13. The light absorbing layers 45 and the upper electrode 13 are made of the materials different from each other, and hence the lattice constants thereof are also different from each other. If the upper electrode 13 is directly laminated on the light absorbing layers 45, therefore, stress resulting from the different lattice constants may be caused in the light absorbing layers 45 and/or the upper electrode 13, to result in lattice defects. The stress resulting from the different lattice constants can be relaxed by interposing the high-resistance buffer layer 46 between the light absorbing layers 45 and the upper electrode 13, whereby the light absorbing layers 45 and the upper electrode 13 can be prevented from formation of lattice defects.

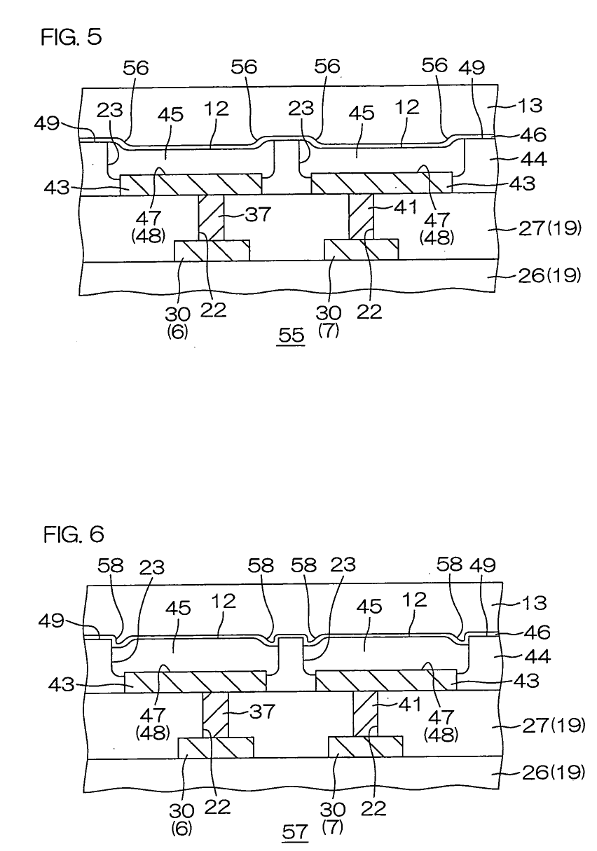

FIG. 5 is a schematic sectional view of a semiconductor device according to a second embodiment of the present invention. Referring to FIG. 5, portions corresponding to those shown in FIGS. 3(a) to 3(c) are denoted by the same reference numerals. In the following, redundant description of the portions denoted by the same reference numerals is omitted.

In the semiconductor device 1 shown in FIGS. 1 to 3(c), the upper surfaces (the photoreceiving surfaces 12) of the light absorbing layers 45 are planar surfaces generally flush with the upper surface 49 of the insulating layer 44. In a semiconductor device 55 shown in FIG. 5, on the other hand, steps 56 are formed on upper surfaces (photoreceiving surfaces 12) of light absorbing layers 45, and a high-resistance buffer layer 46 is formed to cover the steps 56. More specifically, peripheral edge portions of the upper surfaces (the photoreceiving surfaces 12) of the light absorbing layers 45 are generally flush with an upper surface 49 of an insulating layer 44, and central portions of the upper surfaces of the light absorbing layers 45 are lowered by one stage below the peripheral edge portions. Thus, the steps 56 are formed on portions between the peripheral edge portions and the central portions of the upper surfaces of the light absorbing layers 45.

Due to the formation of the steps 56, the area of the photoreceiving surfaces 12 is greater than the opening width of recesses 23. Thus, the surface area (a photoreceiving area) of the photoreceiving surfaces 12 can be rendered greater than the opening area of the recesses 23 (photoreceiving area>opening area). Therefore, sensitivity of a solar cell 4 and an image sensor 5 can be further improved.

The light absorbing layers 45 having the steps 56 can be formed by etching back the light absorbing layers 45 after the step shown in FIG. 4J in place of the CMP step shown in FIG. 4K, for example.

FIG. 6 is a schematic sectional view of a semiconductor device according to a third embodiment of the present invention. Referring to FIG. 6, portions corresponding to those shown in FIGS. 3(a) to 3(c) are denoted by the same reference numerals. In the following, redundant description of the portions denoted by the same reference numerals is omitted.

In a semiconductor device 57 shown in FIG. 6, central portions of upper surfaces (photoreceiving surfaces 12) of light absorbing layers 45 are formed to be generally flush with an upper surface 49 of an insulating layer 44 while peripheral edge portions of the upper surfaces (the photoreceiving surfaces 12) of the light absorbing layers 45 are lowered by one stage below the central portions, whereby steps 58 are formed on the upper surfaces of the light absorbing layers 45. Due to the formation of the steps 58, the area of the photoreceiving surfaces 12 is greater than the opening width of recesses 23. Thus, the surface area (a photoreceiving area) of the photoreceiving surfaces 12 can be rendered greater than the opening area of the recesses 23 (photoreceiving area>opening area). Therefore, sensitivity of a solar cell 4 and an image sensor 5 can be further improved.

The light absorbing layers 45 having the steps 58 can be formed by forming the light absorbing layers 45 to have a thickness generally identical to the depth of the recesses 23 on central portions of the recesses 23 in the step shown in FIG. 4J and removing surface layer portions of the peripheral edge portions of the light absorbing layers 45 on the insulating layer 44 and in the recesses 23 in place of the CMP step shown in FIG. 4K, for example.

### Fourth Embodiment

### 1. Electric Structure of Semiconductor Device

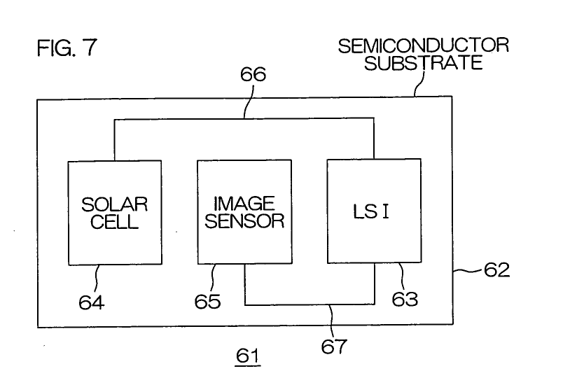

FIG. 7 is a block diagram showing the electric structure of a semiconductor device according to a fourth embodiment of the present invention.

In a semiconductor device 61, an LSI 63, a solar cell 64 and an image sensor 65 are mixedly provided on a semiconductor substrate 62.

The LSI 63 and the solar cell 64 are electrically connected with each other by a power supply line 66 as a power supply circuit. Thus, the LSI 63 and the solar cell 64 are electrically conductible through the power supply line 66. When the solar cell 64 receives light, therefore, power is supplied to the LSI 63.

The LSI 63 and the image sensor 65 are electrically connected with each other by a signal line 67 as a signal circuit insulated from the power supply line 66. Thus, the LSI 63 and the image sensor 65 are electrically conductible through the signal line 67. When the image sensor 65 receives light, therefore, electrons resulting therefrom are converted by a charge reading device (not shown) such as a CMOS device or a CCD to an electric signal, which in turn is input in the LSI 63.

### 2. Plane Structure of Semiconductor Device

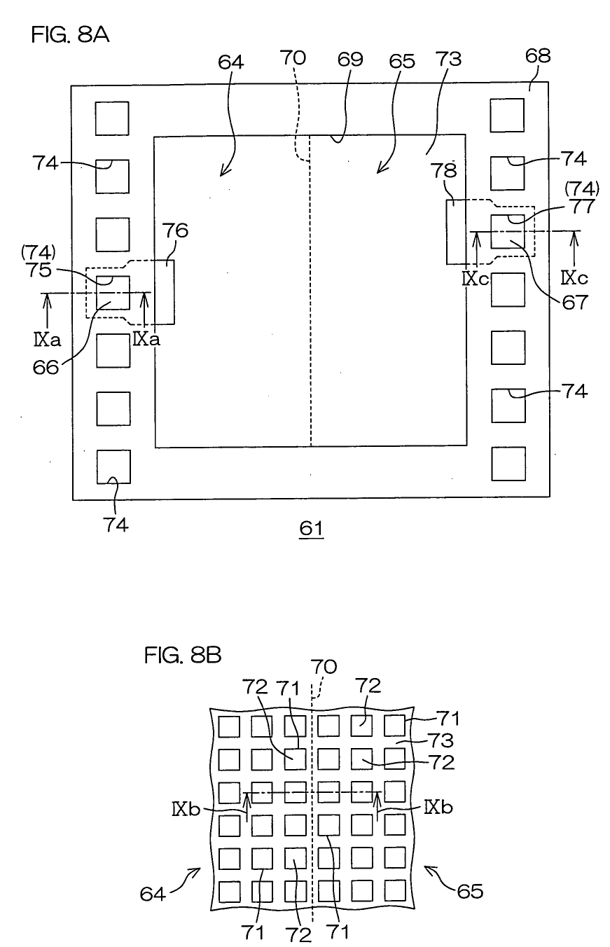

FIG. 8A is a schematic plan view of the semiconductor device 61 according to the fourth embodiment of the present invention. FIG. 8B is an enlarged view of a principal part of the semiconductor device 61 shown in FIG. 8A.

The semiconductor device 61 is quadrangular in plan view. The surface of the semiconductor device 61 is covered with a surface protective film 68 made of silicon nitride.

A photoreceiving opening 69 exposing a central portion of the semiconductor device 61 is formed in the surface protective film 68. The photoreceiving opening 69 is quadrangularly formed in plan view similarly to the semiconductor device 61, so that the sides thereof are parallel to those of the semiconductor device 61. The solar cell 64 and the image sensor 65 face the exterior of the semiconductor device 61 through the photoreceiving opening 69.

When the photoreceiving opening 69 is divided into two rectangular regions line-symmetrical in plan view along a dividing line 70, the solar cell 64 and the image sensor 65 are arranged in one region (a right region in FIGS. 8A and 8B) and another region (a left region in FIGS. 8A and 8B) of the photoreceiving opening 69 respectively, and adjacent to each other through the dividing line 70.

Each of the solar cell 64 and the image sensor 65 has a plurality of photoelectric converters 71 identical in structure to one another, and is constituted of a set of the plurality of photoelectric converters 71. The plurality of photoelectric converters 71 are arranged in the form of a matrix over the entire photoreceiving opening 69. Each photoelectric converter 71 of the solar cell 64 is the minimum generating unit (unit cell) converting light energy to power, while each photoelectric converter 71 of the image sensor 65 is one pixel of image information.

The dividing line 70 demarcating the solar cell 64 and the image sensor 65 from each other is set between the photoelectric converters 71 of the solar cell 64 and those of the image sensor 65.

The plurality of photoelectric converters 71 arranged in the aforementioned manner have photoreceiving surfaces 72 on portions facing the exterior of the semiconductor device 61 respectively. All photoreceiving surfaces 72 are integrally formed by one upper electrode 73. In other words, an electrode on photoreceiving sides of the solar cell 64 and the image sensor 65 is shared by all photoelectric converters 71 without distinction of the solar cell 64 or the image sensor 65.

In the surface protective film 68, a plurality of pad openings 74 are formed on both sides of the photoreceiving opening 69 in the adjacent direction (orthogonal to the dividing line 70) of the solar cell 64 and the image sensor 65, to be separated from the photoreceiving opening 69. The plurality of pad openings 74 are provided on both sides of the photoreceiving opening 69 in the same numbers respectively, and arranged at regular intervals in a direction parallel to the dividing line 70.

A wire electrically connected with the LSI 63 is exposed in each pad opening 74. One of the plurality of pad openings 74 arranged on one side of the photoreceiving opening 69 is a power supply pad opening 75 exposing the power supply line 66. The power supply line 66 exposed from the power supply pad opening 75 is electrically connected with the upper electrode 73 by a power extraction electrode 76 (made of Al, for example) extending over the photoreceiving opening 69 and the power supply pad opening 75.

On the other hand, one of the plurality of pad openings 74 arranged one the other side of the photoreceiving opening 69 is a signal pad opening 77 exposing the signal line 67. The signal line 67 exposed from the signal pad opening 77 is electrically connected with the upper electrode 73 by a signal extraction electrode 78 (made of Al, for example) extending over the photoreceiving opening 69 and the signal pad opening 77.

### 3. Sectional Structure of Semiconductor Device

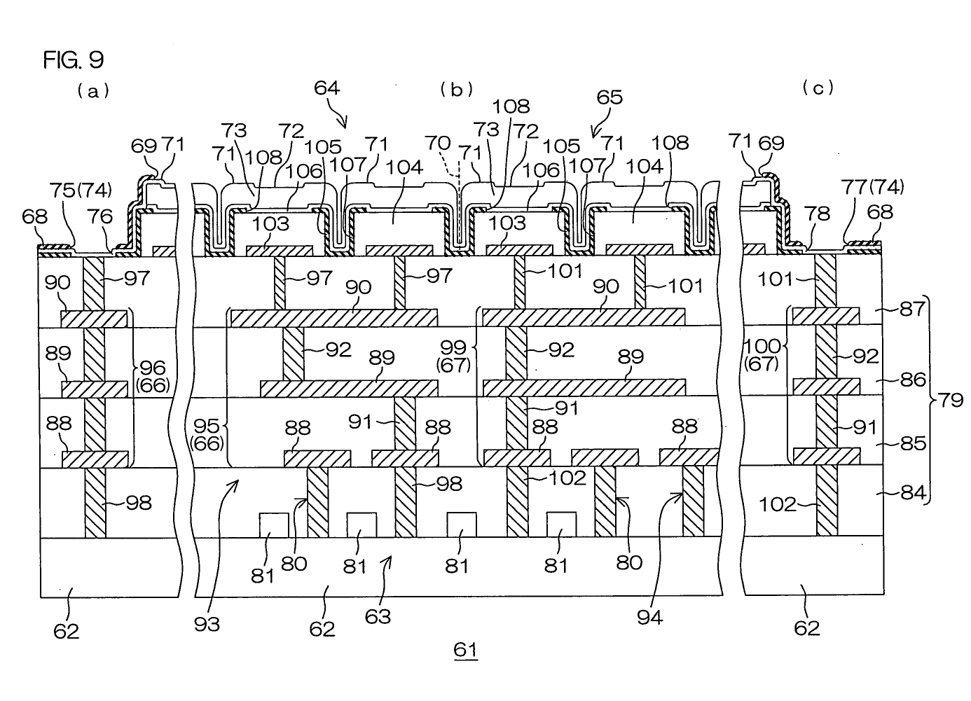

FIGS. 9(a), 9(b) and 9(c) are schematic sectional views of the semiconductor device 61 according to the fourth embodiment of the present invention taken along a line IXa-IXa in FIG. 8A, a line IXb-IXb in FIG. 8B and a line IXc-IXc in FIG. 8A respectively.

In the semiconductor device 61, the LSI 63, the solar cell 64 and the image sensor 65 are stacked and arranged on the semiconductor substrate 62. More specifically, the LSI 63 is formed on the semiconductor substrate 62, and an interlayer film 79 is laminated on the LSI 63. The solar cell 64 and the image sensor 65 are arranged on the interlayer film 79 to be adjacent to each other. Thus, the solar cell 64 and the image sensor 65 are stacked on the LSI 63 through the interlayer film 79.

The semiconductor substrate 62 is made of silicon, for example. The semiconductor substrate 62 is 2 mm to 7 mm square and has a thickness of 200 μm to 725 μm, for example.

The LSI 63 includes a plurality of types of circuit elements 81. The plurality of types of circuit elements 81 include transistors (Tr), capacitors (C), registers (R) and the like, for example.

The interlayer film 79 is made of silicon oxide, and formed by laminating a first interlayer film 84, a second interlayer film 85, a third interlayer film 86 and a fourth interlayer film 87 successively from the side closer to the LSI 63.

First to third wires 88 to 90 are formed on the interlayer films 84 to 86 successively from the side of the first interlayer film 84 respectively. The first to third wires 88 to 90 are made of Al (melting point: about 500° C.), for example.

First via plugs 91 passing through the second interlayer film 85 and second via plugs 92 passing through the third interlayer film 86 electrically connect the first and second wires 88 and 89 and the second and third wires 89 and 90 with one another respectively. The first and second via plugs 91 and 92 are made of W (melting point: about 3400° C.), for example. The first to third wires 88 to 90 are electrically connected with one another over the first to third interlayer films 84 to 86, thereby forming a multilayer interconnection structure 93 extending over the first to third interlayer films 84 to 86.

The multilayer interconnection structure 93 at least includes the power supply line 66 electrically connecting the solar cell 64 and the LSI 63 with each other and the signal line 67 electrically connecting the image sensor 65 and the LSI 63 with each other, and additionally includes interelement circuits 80 electrically connecting the plurality of types of circuit elements 81 with one another and partially forming the LSI 63 and an output circuit 94 transmitting signals output from the LSI 63, for example.

The power supply line 66 has an anode power supply wire 95 and a cathode power supply wire 96. The anode power supply wire 95 is arranged under the solar cell 64. Power supply via plugs 97 electrically connect the anode power supply wire 95 and the solar cell 64 with each other, while a power supply contact plug 98 electrically connects the anode power supply wire 95 and the LSI 63 with each other. The power supply via plugs 97 and the power supply contact plug 98 are made of W (melting point: about 3400° C.), for example.

On the other hand, the cathode power supply wire 96 is arranged on a side portion of the solar cell 64. The aforementioned power extraction electrode 76 and a power supply via plug 97 electrically connect the cathode power supply wire 96 and the solar cell 64 with each other, while a power supply contact plug 98 electrically connects the cathode power supply wire 96 and the LSI 63 with each other.

The signal line 67 has an anode signal wire 99 and a cathode signal wire 100. The anode signal wire 99 is arranged under the image sensor 65. Signal via plugs 101 electrically connect the anode signal wire 99 and the image sensor 65 with each other, while a signal contact plug 102 electrically connects the anode signal wire 99 and the LSI 63 with each other. The signal via plugs 101 and the signal contact plug 102 are made of W (melting point: about 3400° C.), for example.

On the other hand, the cathode signal wire 100 is arranged on a side portion of the image sensor 65. The aforementioned signal extraction electrode 78 and a signal via plug 101 electrically connect the cathode signal wire 100 and the image sensor 65 with each other, while a signal contact plug 102 electrically connects the cathode signal wire 100 and the LSI 63 with each other.

The photoelectric converters 71 constituting the solar cell 64 and the image sensor 65 include lower electrodes 103, light absorbing layers 104, an oxide film 105, a buffer layer 106 and the upper electrode 73.

The lower electrodes 103 are made of Mo (molybdenum) or W (tungsten), for example, and formed on the fourth interlayer film 87. In the lower electrodes 103, those for the solar cell 64 are electrically connected with the power supply via plugs 97, and those for the image sensor 65 are electrically connected with the signal via plugs 101. The thickness of the lower electrodes 103 is 4000 Å, for example.

The light absorbing layers 104 are made of a P-type compound semiconductor having a chalcopyrite structure.

As the compound semiconductor having the chalcopyrite structure, a I-III-VI₂ type chalcopyrite semiconductor is preferably applied, and a CIGS-based semiconductor expressed as Cu(Inₓ, Ga₍₁₋ₓ₎) Se₂ (0≦x≦1) is more preferably applied. In particular, the chalcopyrite compound semiconductor preferably contains Ga (i.e. 0≦x≦1).

The light absorbing layers 104 are formed to cover the upper surfaces and the side surfaces of the lower electrodes 103. The thickness of the light absorbing layers 104 (the height from the upper surface of the third interlayer film 86) is 1 μm, for example. A clearance 107 of 1 μm, for example, is provided between the light absorbing layer 104 of each photoelectric converter 71 and the light absorbing layer 104 of the photoelectric converter 71 adjacent thereto.

The oxide film 105 covers the upper surfaces of the light absorbing layers 104 of the photoelectric converters 71 and enters the clearances 107 between the light absorbing layers 104 adjacent to one another, thereby isolating the light absorbing layers 104 from one another. The oxide film 105 is integrally formed to cover the light absorbing layers 104 of all photoelectric converters 71. Te thickness of the oxide film 105 is 4000 Å, for example. Junction openings 108 exposing the upper surfaces of the light absorbing layers 104 of the photoelectric converters 71 respectively is formed in the oxide film 105.

The buffer layer 106 is made of CdS (cadmium sulfide), for example. The buffer layer 106 is formed to cover the surface of the oxide film 105 and the upper surfaces of the light absorbing layers 104 exposed from the junction openings 108. The thickness of the buffer layer 106 is 50 nm, for example.

The upper electrode 73 is formed on the buffer layer 106, and exposed from the photoreceiving opening 69. The upper electrode 73 is formed by laminating a non-doped ZnO film and an N-type ZnO film in this order. The non-doped ZnO film contains no impurity added thereto, and has higher resistance than the N-type ZnO film.

On the other hand, the N-type ZnO film, forming the photoreceiving surfaces 72 of the photoelectric converters 71, is a conductive transparent electrode containing an N-type impurity (impurity concentration: 1.5 wt. %). The thickness of the non-doped ZnO film is 1000 Å, for example, and the thickness of the n-type ZnO film is 5000 Å, for example.

Thus, the thickness of the non-doped ZnO film is rendered sufficiently smaller than that of the N-type ZnO film, whereby a P-N junction can be formed between the N-type ZnO film of the upper electrode 73 and the P-type light absorbing layers 104. The upper electrode 73 is electrically connected with the cathode power supply wire 96 through the power extraction electrode 76 and the corresponding power supply via plug 97 (see FIG. 9(a)), and electrically connected with the cathode signal wire 100 through the signal extraction electrode 78 and the corresponding signal via plug 101 (see FIG. 9(c)).

### 4. Method for Manufacturing Semiconductor Device

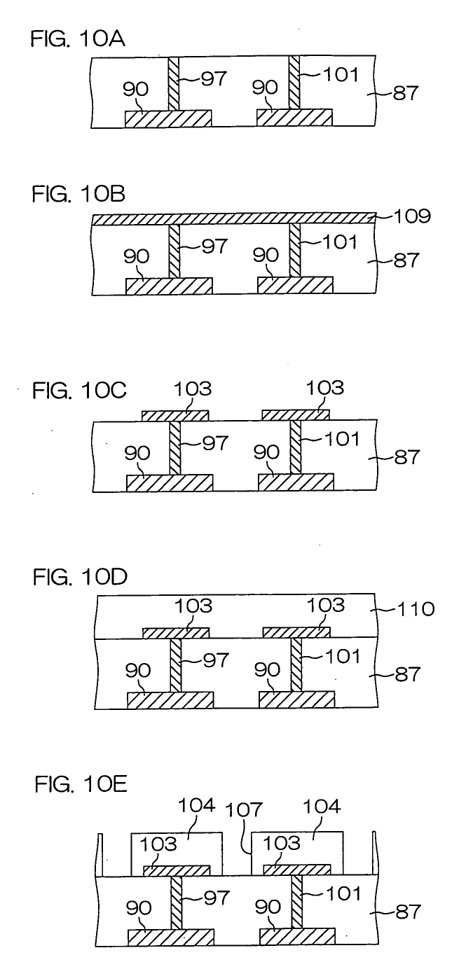

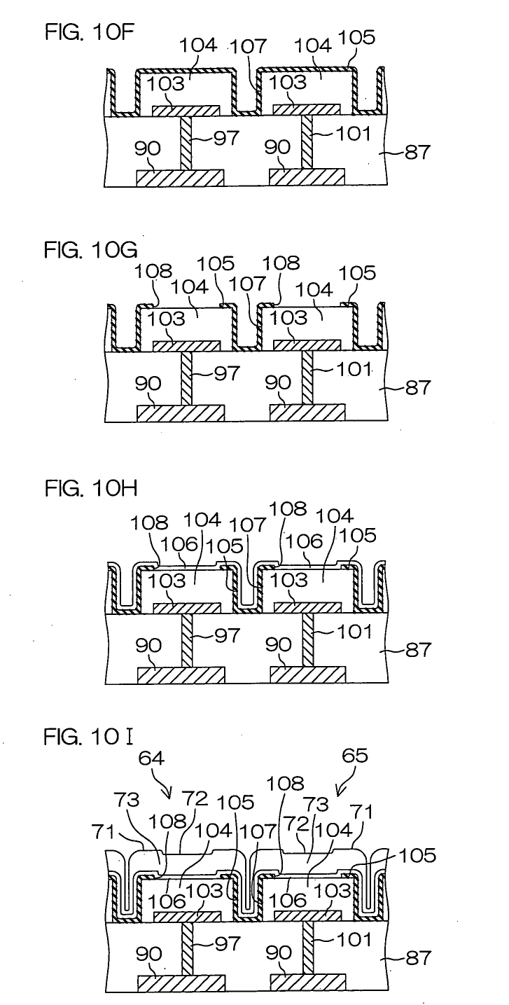

FIGS. 10A to 10I are schematic sectional views showing a method for manufacturing the semiconductor device 61 shown in FIGS. 9(a) to 9(c). Each of FIGS. 10A to 10I shows one of the photoelectric converters 71 constituting the solar cell 64 and one of those constituting the image sensor 65.

In order to manufacture the aforementioned semiconductor device 61, the various types of circuit elements 81 are first loaded on the semiconductor substrate 62 by a well-known element integration technique. Then, the interlayer film 79 as well as the power supply line 66 and the signal line 67 are formed by a well-known multilayer interconnection technique. Then, contact holes are formed in the fourth interlayer film 87 and each power supply via plug 97 and each signal via plug 101 are simultaneously formed to fill up the contact holes, as shown in FIG. 10A.

Then, an Mo material 109 (or a W material) is deposited on the fourth interlayer film 87 by sputtering, for example, as shown in FIG. 10B.

Then, the Mo material 109 (or the W material) is patterned by a well-known technique, as shown in FIG. 10C. Thus, the lower electrodes 103 are formed.

Then, a compound semiconductor having a chalcopyrite structure is grown by MBE (Molecular Beam Epitaxy), for example, under a temperature condition of 300° C. to 450° C., to form a chalcopyrite thin film 110, as shown in FIG. 10D. At this time, respective elements are supplied at prescribed ratios. In a case of a CIGS semiconductor, for example, Cu, In, Ga and Se elements are supplied at prescribed ratios. Further, Mg, for example, can be applied as a P-type impurity for forming the chalcopyrite thin film 110.

Then, the chalcopyrite thin film 110 is dry-etched in a latticed manner with PZT (lead zirconate titanate), for example, as shown in FIG. 10E. Thus, the clearances 107 are formed, and the plurality of light absorbing layers 104 are formed to be demarcated from one another through the clearances 107.

Then, the oxide film 105 made of silicon oxide is formed by plasma CVD employing TEOS, for example, as shown in FIG. 10F.

Then, the junction openings 108 are formed in the oxide film 105 by well-known lithography and etching, for example, as shown in FIG. 10G. Further, openings (not shown) exposing the cathode power supply wire 96 and the cathode signal wire 100 are formed at the same time.

Then, a CdS material is deposited by CBD (Chemical Bath Deposition), for example, as shown in FIG. 10H. Thus, the buffer layer 106 is formed.

Then, a non-doped ZnO film and an N-type ZnO film are deposited in this order by sputtering, for example, as shown in FIG. 10I. Then, unnecessary portions (portions other than the upper electrode 73) of the deposited films are removed by etching. Thus, the upper electrode 73 is formed, to form the photoelectric converters 71.

Thereafter the power extraction electrode 76 and the signal extraction electrode 78 are formed by depositing Al by sputtering and thereafter patterning the same, for example, although this step is not shown. Then, the surface protective film 68 is formed, followed by formation of the photoreceiving opening 69 and the pad openings 74 (the power supply pad opening 75 and the signal pad opening 77).

The semiconductor device 61 is obtained through the aforementioned steps.

In the semiconductor device 61, the interlayer film 79 is laminated on the semiconductor substrate 62 provided with the LSI 63, and the solar cell 64 and the image sensor 65 are stacked and arranged on the LSI 63 through the interlayer film 79. The solar cell 64 and the image sensor 65 can be stacked and arranged on the LSI 63 since the light absorbing layers 104 of the photoelectric converters 71 are made of the compound semiconductor having the chalcopyrite structure. This is because the compound semiconductor having the chalcopyrite structure can be formed by MBE at a temperature of 300° C. to 450° C., for example, and hence influence exerted on the LSI 63 by the formation of the photoelectric converters 71 can be reduced. For example, the first to third wires 88 to 90 can be prevented from melting.

The solar cell 64 and the image sensor 65 can be stacked and arranged on the LSI 63, whereby the LSI 63, the solar cell 64 and the image sensor 65 can be integrated into one chip. Consequently, the semiconductor device 61 can be inhibited from increase in size.

Further, the solar cell 64 and the image sensor 65 are stacked and arranged on the LSI 63, whereby generally the overall regions of arrangement areas on the interlayer film 79 can be employed as the photoreceiving surfaces 72 of the photoelectric converters 71. Therefore, the degree of freedom in design of the size of the photoelectric converters 71 can be increased. Thus, the open area ratio of the photoelectric converters 71 constituting the solar cell 64 and the image sensor 65 respectively can be set to 80% to 100%, for example. Consequently, a sufficient photoreceiving area can be ensured for the photoelectric converters 71, whereby reduction in the quantum efficiency of the photoelectric converters 71 can be suppressed.

The solar cell 64 and the LSI 63 are electrically connected with each other through the power supply line 66. When light is introduced from the photoreceiving surfaces 72 of the photoelectric converters 71 of the solar cell 64, therefore, electrons in the N-type upper electrode 73 are extracted by the power extraction electrode 76 due to the light energy, and supplied to the LSI 63 through the cathode power supply wire 96. The electrons are continuously supplied while the solar cell 64 receives the light, whereby a current flows from the light absorbing layers 104 to successively reach the anode power supply wire 95, the LSI 63, the cathode power supply wire 96, the power extraction electrode 76 and the upper electrode 73. Thus, power is supplied to the LSI 63.

Therefore, the LSI 63 can be operated with no requirement for separate power supply. Further, a power supply device can be omitted, whereby the semiconductor device 61 can be downsized.

The image sensor 65 and the LSI 63 are electrically connected with each other through the signal line 67. When light is introduced from the photoreceiving surfaces 72 of the photoelectric converters 71 of the image sensor 65, therefore, electrons in the upper electrode 73 generated by the light energy are converted by the charge reading device to electric signals, which in turn are thereafter extracted by the signal extraction electrode 78 and input in the LSI 63 through the cathode signal wire 100. The electric signals are continuously input while the image sensor 65 receives the light, whereby the electric signals flow from the light absorbing layers 104 to successively reach the anode signal wire 99, the LSI 63, the cathode signal wire 100, the signal extraction electrode 78 and the upper electrode 73.

The image sensor 65 and the solar cell 64 are used together, whereby the LSI 63 can process signals received from the plurality of photoelectric converters 71 constituting the image sensor 65 with the power supplied from the solar cell 64. Thus, the LSI 63 can detect the light input in the image sensor 65 as image information.

When the light absorbing layers 104 contain Ga, the quantum efficiency of the photoelectric converters 71 can be improved. For example, excellent quantum efficiency of about 80% to 90% can be implemented.

According to the fourth embodiment, the light absorbing layers 104 are cut into respective pixel units by etching in the step shown in FIG. 10E. Thus, the interval between the light absorbing layers 104 is decided. According to the method, it is difficult to perform fine processing for increasing an aspect ratio to not less than a constant level when cutting the light absorbing layers 104 into the pixel units. Therefore, the interval between the cut light absorbing layers 104 is increased, to easily reduce the surface area of the upper surfaces of the light absorbing layers 104.

In the step shown in FIG. 10G, the junction openings 108 are formed with margins with respect to peripheral edges of the light absorbing layers 104 in consideration of misregistration of the junction openings 108 formed in the oxide film 105 with respect to the light absorbing layers 104. Therefore, the surfaces (the photoreceiving surfaces) of the light absorbing layers 104 exposed from the junction openings 108 are smaller than the upper surfaces of the light absorbing layers 104.

Thus, in the semiconductor device 61, the surface area of the upper surfaces of the light absorbing layers 104 is easily reduced while the photoreceiving surfaces are smaller than the upper surfaces of the light absorbing layers 104, and hence the sensitivity of each light absorbing layer 104 is lower than that of each light absorbing layer 45 according to each of the first to third embodiments.

The etching step for cutting the light absorbing layers 104 into the pixel units is the so-called dry etching step. In other words, the light absorbing layers 104 are physically etched by colliding particles with the surfaces of the light absorbing layers 104, and hence the side surfaces (surfaces formed by the etching) of the light absorbing layers 104 are easily roughened. Consequently, the light absorbing layers 104 are dispersed in size, and hence easily dispersed in sensitivity.

In order to manufacture the solar cell 64 and the image sensor 65, further, at least three photolithography steps are required. Therefore, the manufacturing cost for the solar cell 64 and the image sensor 65 is higher than that for the solar cell 4 and the image sensor 5 according to each of the first to third embodiments.

Comparing the semiconductor device 1 according to each of the first to third embodiments and the semiconductor device 61 according to the fourth embodiment with each other, therefore, the former can more improve and uniformize the sensitivity of the light absorbing layers 45 and reduce the manufacturing cost.

While the embodiments of the present invention have been described, the present invention may be embodied in other ways.

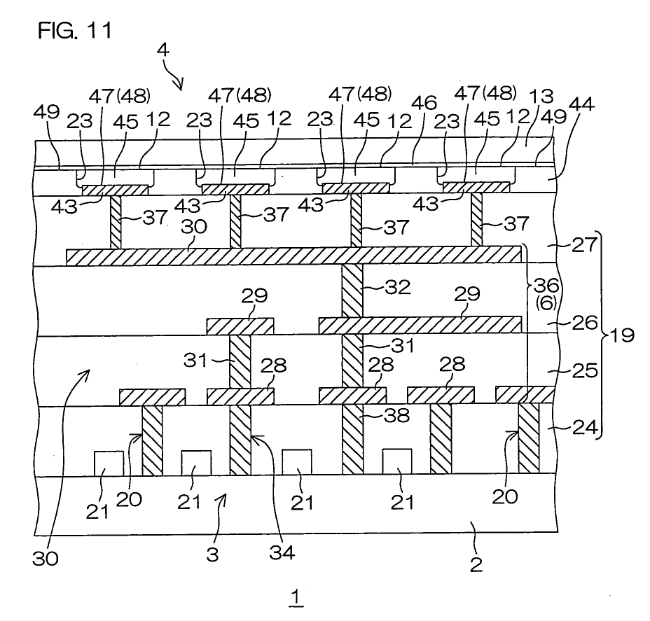

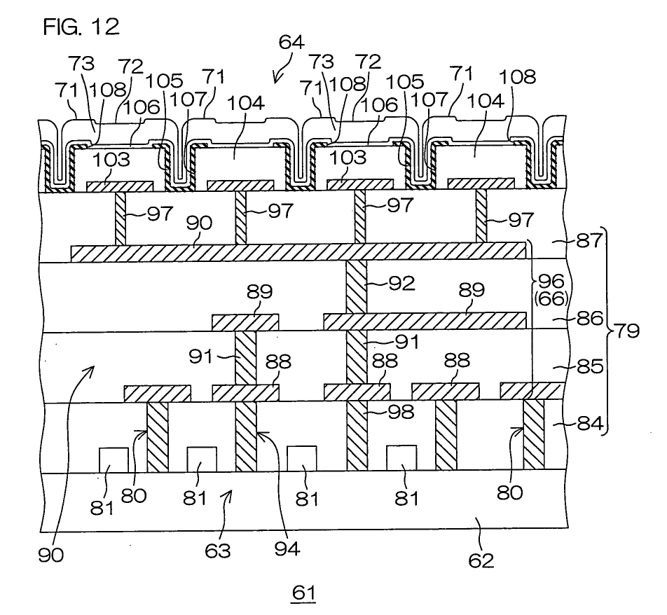

For example, the semiconductor devices 1 and 61 may not include the image sensors 5 and 65, as shown in FIG. 11 (a fifth embodiment) and FIG. 12 (a sixth embodiment) respectively. In other words, the photoelectric converters 11 and 71 may constitute only the solar cell 4 and 64. To the contrary, the photoelectric converters 11 and 71 may constitute only the image sensors 5 and 65.

The integrated circuit formed on each semiconductor substrate 2 or 62 is not restricted to the LSI, but may be an SSI, an MSI, a VLSI or an ULSI, for example.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2009-072561 filed with the Japan Patent Office on Mar. 24, 2009, Japanese Patent Application No. 2009-095193 filed with the Japan Patent Office on Apr. 9, 2009 and Japanese Patent Application No. 2010-065681 filed with the Japan Patent Office on Mar. 23, 2010, the disclosures of which are incorporated herein by reference.

What is claimed is:

1. A semiconductor device comprising:
a semiconductor substrate;
an integrated circuit formed on the semiconductor substrate; and
a photoelectric converter, stacked on the integrated circuit, having a light absorbing layer made of a compound semiconductor having a chalcopyrite structure.

2. The semiconductor device according to claim 1, wherein
a solar cell is constituted of a plurality of photoelectric converters, and
the semiconductor device further comprises a power supply circuit electrically connecting the solar cell and the integrated circuit with each other.

3. The semiconductor device according to claim 1, wherein
an image sensor is constituted of a plurality of photoelectric converters, and
the semiconductor device further comprises a signal circuit electrically connecting the image sensor and the integrated circuit with each other.

4. The semiconductor device according to claim 1, wherein
the light absorbing layer contains Ga.

5. The semiconductor device according to claim 1, wherein
the photoelectric converter includes:
a first insulating layer;
a lower electrode formed on the first insulating layer; and
a second insulating layer, laminated on the first insulating layer, having a recess including the upper surface of the lower electrode in the bottom surface thereof,
the light absorbing layer is embedded in the recess and the upper surface thereof is a photoreceiving surface having a surface area of not less than the opening area of the recess, and
an upper electrode made of a light-transmitting material is formed on the light absorbing layer.

6. The semiconductor device according to claim 5, wherein
the opening area of the recess is greater than the area of the upper surface of the lower electrode, and
the bottom surface of the recess includes the overall region of the upper surface of the lower electrode.

7. The semiconductor device according to claim 5, wherein
the photoreceiving surface is flush with the upper surface of the second insulating layer.

8. The semiconductor device according to claim 5, further comprising a buffer layer interposed between the light absorbing layer and the upper electrode.

9. The semiconductor device according to claim 5, wherein
a step is formed in the photoreceiving surface between a peripheral edge portion of the photoreceiving surface and a central portion surrounded by the peripheral edge portion.

10. The semiconductor device according to claim 9, wherein
the step is formed by lowering the central portion of the photoreceiving surface by one stage below the peripheral edge portion of the photoreceiving surface.

11. A photoelectric converter comprising:
a first insulating layer;
a lower electrode formed on the first insulating layer;
a second insulating layer, laminated on the first insulating layer, having a recess including the upper surface of the lower electrode in the bottom surface thereof;
a light absorbing layer, made of a chalcopyrite-based compound semiconductor and embedded in the recess, having an upper surface serving as a photoreceiving surface; and
an upper electrode made of a light-transmitting material formed on the light absorbing layer, wherein
the surface area of the photoreceiving surface is not less than the opening area of the recess.

12. The photoelectric converter according to claim 11, wherein
the opening area of the recess is greater than the area of the upper surface of the lower electrode, and
the bottom surface of the recess includes the overall region of the upper surface of the lower electrode.

13. The photoelectric converter according to claim 11, wherein
the photoreceiving surface is flush with the upper surface of the second insulating layer.

14. The photoelectric converter according to claim 11, further comprising a buffer layer interposed between the light absorbing layer and the upper electrode.

15. The photoelectric converter according to claim 11, wherein
a step is formed in the photoreceiving surface between a peripheral edge portion of the photoreceiving surface and a central portion surrounded by the peripheral edge portion.

16. The photoelectric converter according to claim 15, wherein
the step is formed by lowering the central portion of the photoreceiving surface by one stage below the peripheral edge portion of the photoreceiving surface.

17. A method for manufacturing a photoelectric converter, comprising the steps of:
laminating an electrode material layer made of a material for a lower electrode on a first insulating layer;
laminating a sacrificial layer on the electrode material layer;
selectively removing the sacrificial layer and the electrode material layer by photolithography and etching;
forming a second insulating layer on the first insulating layer so that at least the removed portions of the sacrificial layer and the electrode material layer are filled up to the upper surface of the sacrificial layer;
chemically mechanically polishing the second insulating layer for exposing the upper surface of the sacrificial layer to be flush with the upper surface of the second insulating layer;
removing the sacrificial layer by isotropic etching after the chemical mechanical polishing of the second insulating layer;
depositing a chalcopyrite-based compound semiconductor to fill up a recess formed in the second insulating layer due to the removal of the sacrificial layer; and
chemically mechanically polishing the deposition layer of the chalcopyrite-based compound semiconductor for forming a light absorbing layer embedded in the recess.
